(19) United States
(12) Patent Application Publication
(10) Pub. No.: US 2025/0286454 A1
(43) Pub. Date: Sep. 11, 2025

(54) VOLTAGE CONVERTER, MEMORY MODULE INCLUDING VOLTAGE CONVERTER, AND OPERATING METHOD OF VOLTAGE CONVERTER

(71) Applicant: Samsung Electronics Co., Ltd., Suwon-si (KR)

(72) Inventors: Donghee CHO, Suwon-si (KR); Taesung KIM, Suwon-si (KR); HOCHEOL NOH, Suwon-si (KR); Sangcheol MOON, Suwon-si (KR); Bonggeun CHUNG, Suwon-si (KR)

(21) Appl. No.: 18/928,313

(22) Filed: Oct. 28, 2024

(30) Foreign Application Priority Data
Mar. 6, 2024 (KR) 10-2024-0032032

(51) Int. Cl. H02M 3/158; G11C 5/14; H02M 1/44

(52) U.S. Cl. CPC H02M 3/158; G11C 5/147; H02M 1/44

(57) ABSTRACT

Disclosed is a voltage converter, which includes a converting circuit that converts an input voltage into an output voltage, an offset generation circuit that generates an offset voltage, a ripple addition circuit that receives the output voltage and a first voltage from the converting circuit, receives the offset voltage from the offset generation circuit, and generates a ripple voltage based on the output voltage, the first voltage, and the offset voltage, and a controller that receives the ripple voltage, switches the converting circuit based on the ripple voltage, and controls a timing at which the offset generation circuit generates the offset voltage and a timing at which the offset generation circuit does not generate the offset voltage.

### CROSS-REFERENCE TO RELATED APPLICATIONS

This application claims priority under 35 U.S.C. § 119 to Korean Patent Application No. 10-2024-0032032 filed on Mar. 6, 2024, in the Korean Intellectual Property Office, the disclosure of which is incorporated by reference herein in its entirety.

### BACKGROUND

Embodiments of the present disclosure described herein relate to an electronic device, and more particularly, relate to a voltage converter with improved characteristics and improved response speed, a memory module including the voltage converter, and a method of operating the voltage converter.

Electronic devices may receive a single input voltage from a voltage source. The electronic devices may operate using various internal voltages, and levels of the internal voltages may be different from a level of the input voltage. To generate various internal voltages, the electronic devices may include a voltage converter that converts an input voltage to an internal voltage.

The voltage converter may include a buck converter and a boost converter. A buck converter may convert an input voltage to an output voltage that is lower than the input voltage. A boost converter may convert an input voltage to an output voltage that is higher than the input voltage. As an example, the buck-boost converter may selectively perform a buck conversion and a boost conversion when the level of the input voltage varies.

The voltage converters may have various operating modes. When a voltage converter switches its operating mode, the voltage converter's output voltage may change. Moreover, when the voltage converter switches its operating mode, the faster the output voltage changes to a target voltage, the better the voltage converter's response speed may be.

Alternatively, when the voltage converter switches its operating mode, undershoot or overshoot may occur in the output voltage. When the voltage converter switches its operating mode, to the extent that undershoot or overshoot in the output voltage is suppressed, the voltage converter's operating characteristics may be improved.

### SUMMARY

Embodiments of the present disclosure provide a voltage converter with improved response speed and improved operation characteristics, a memory module including the voltage converter, and a method of operating the voltage converter.

According to an embodiment of the present disclosure, a voltage converter includes a voltage converting circuit that converts an input voltage into an output voltage, an offset generation circuit that generates an offset voltage, a ripple addition circuit that receives the output voltage and a first voltage from the voltage converting circuit, receives the offset voltage from the offset generation circuit, and generates a ripple voltage based on the output voltage, the first voltage, and the offset voltage, and a controller that receives the ripple voltage, controls switches in the voltage converting circuit based on the ripple voltage, and controls a timing at which the offset generation circuit generates the offset voltage and a timing at which the offset generation circuit does not generate the offset voltage.

According to an embodiment of the present disclosure, a memory module includes a plurality of memory devices, a driver that receives commands, addresses, and clock signals from an external device and transfers the commands, the addresses, and the clock signals to the plurality of memory devices, and a voltage converter that receives an input voltage from the external device, converts the input voltage into an output voltage, and provides the output voltage to the plurality of memory devices, and the voltage converter includes a voltage converting circuit that converts the input voltage into the output voltage, an offset generation circuit that generates an offset voltage, a ripple addition circuit that receives the output voltage and a first voltage from the voltage converting circuit, receives the offset voltage from the offset generation circuit, and generates a ripple voltage based on the output voltage, the first voltage, and the offset voltage, and a controller that receives the ripple voltage, controls the voltage converting circuit based on the ripple voltage, and controls a timing at which the offset generation circuit generates the offset voltage and a timing at which the offset generation circuit does not generate the offset voltage.

According to an embodiment of the present disclosure, a method of operating a voltage converter includes converting an input voltage to generate an output voltage from the input voltage based on a switching control signal, in a first time period, generating a ripple voltage by adding a ripple and an offset to the output voltage, in a second time period, generating the ripple voltage by adding the ripple to the output voltage, and adjusting a timing of converting the input voltage based on the ripple voltage in the first time period and the second time period.

### BRIEF DESCRIPTION OF THE FIGURES

The above and other objects and features of the present disclosure will become apparent by describing in detail embodiments thereof with reference to the accompanying drawings.

FIG. 1 illustrates a voltage converter, according to a first embodiment of the present disclosure.

FIG. 2 illustrates an operating method of a voltage converter, according to an embodiment of the present disclosure.

FIG. 3 illustrates a detailed example of a voltage converter.

FIG. 4 illustrates examples of a first voltage, a ripple voltage, and a comparison voltage.

FIG. 5 illustrates examples of a first operating mode and a second operating mode of a voltage converter.

FIG. 6 illustrates an example of how a voltage converter malfunctions when a ripple is reduced.

FIG. 7 illustrates a voltage converter, according to a second embodiment of the present disclosure.

FIG. 8 illustrates an operating method of a voltage converter, according to an embodiment of the present disclosure.

FIG. 9 illustrates more detailed example of a voltage converter.

FIG. 10 illustrates an example of how a voltage converter operates when a comparator has hysteresis.

FIG. 11 illustrates an offset generation circuit, according to an embodiment of the present disclosure.

FIG. 12 illustrates a memory module MOD, according to an embodiment of the present disclosure.

FIG. 13 is a block diagram illustrating a computing device, according to an embodiment of the present disclosure.

FIG. 14 illustrates an example of an operating method of a computing device 1100.

### DETAILED DESCRIPTION

Hereinafter, embodiments of the present disclosure will be described in detail and clearly to such an extent that one of ordinary skill in the art can readily implement the present invention.

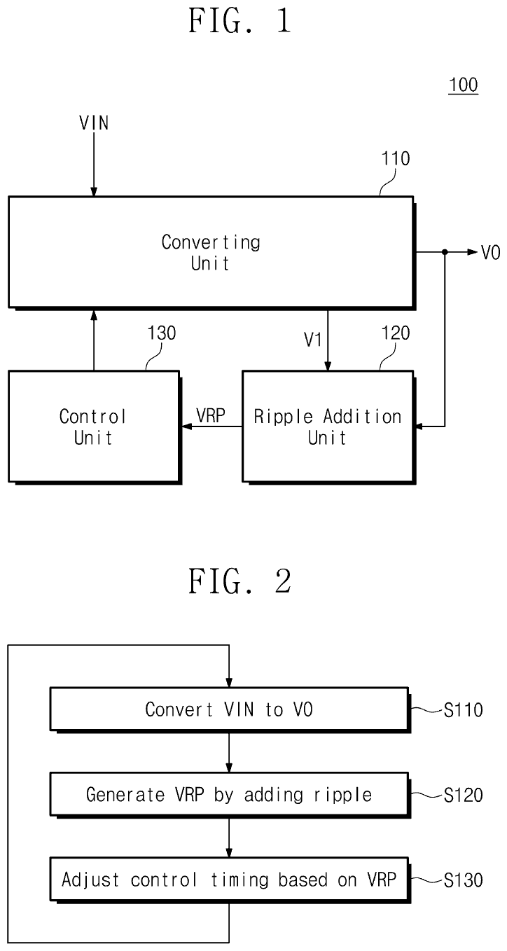

FIG. 1 illustrates a voltage converter 100, according to a first embodiment of the present disclosure. Referring to FIG. 1, the voltage converter 100 may include a converting unit or converting circuit 110 (e.g., a voltage converting circuit), a ripple addition unit or ripple addition circuit 120, and a control unit or controller 130.

The converting circuit 110 may be a circuit that receives an input voltage VIN. Based on a control from the controller 130 (e.g., a control signal sent from the controller 130), the converting circuit 110 may convert the input voltage VIN into an output voltage VO. For example, the converting circuit 110 may include a plurality of switching elements. In response to the controller 130 controlling one or more of the plurality of switching elements to be in particular states, the converting circuit 110 may convert the input voltage VIN to the output voltage VO.

In an example, a level of the input voltage VIN may be fixed. A target level of the output voltage VO may be lower than the level of the input voltage VIN. In such an example, the converting circuit 110 may perform a buck conversion, thereby reducing the input to the target output level.

The ripple addition circuit 120 may then receive the output voltage VO and a first voltage V1 from the converting circuit 110. For example, the first voltage V1 may be an internal voltage of the converting circuit 110. The ripple addition circuit 120 may generate a ripple voltage VRP based on the output voltage VO and the first voltage V1. The generated ripple voltage VRP may simulate an inductor current from a switching voltage associated with the controller 130.

As an example, the ripple addition circuit 120 may generate a ripple corresponding to a switching period in which the controller 130 controls the converting circuit 110 (e.g., switching the settings or mode of the converting circuit 110), based on the first voltage V1. For example, the ripple may rise during a first time period of the switching period and may fall during a second time period of the switching period. The ripple addition circuit 120 may add the ripple to the output voltage VO and may output the added result as a ripple voltage VRP. In this example, the ripple voltage VRP may rise during a first time period of the switching period and may fall during a second time period of the switching period.

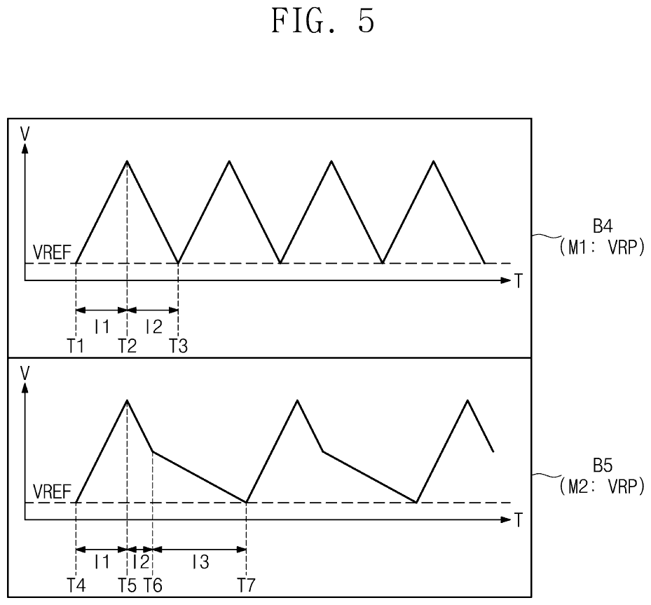

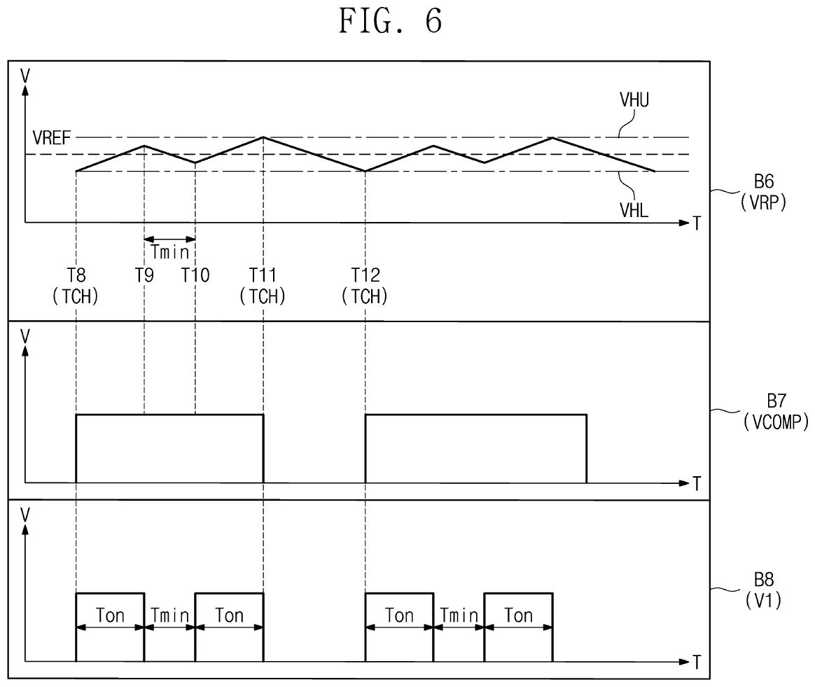

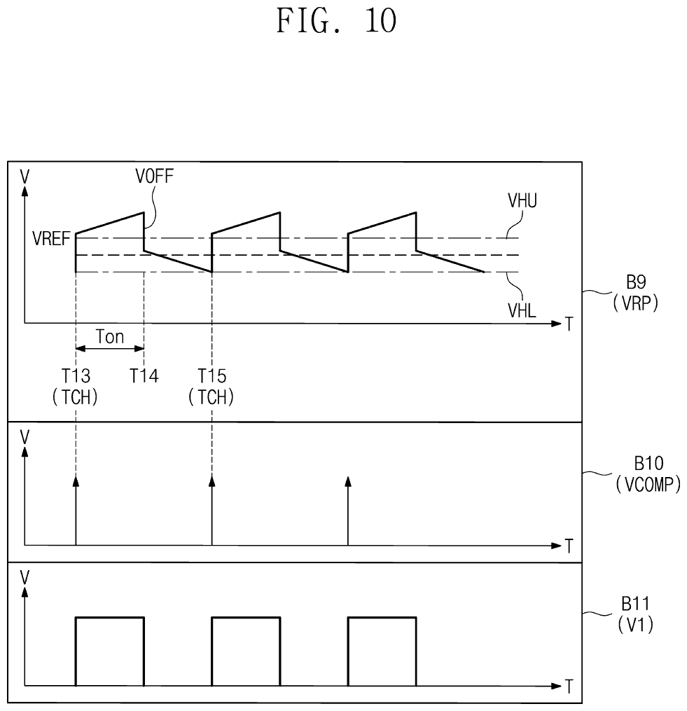

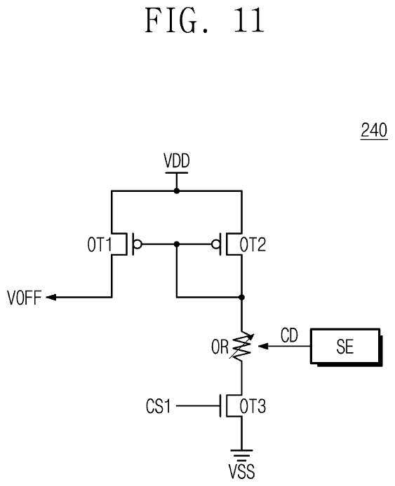

The ripple voltage VRP may prevent malfunction of the voltage converter 100 in the presence of hysteresis, as described below in the examples of FIGS. 6 and 10. However, ripple voltage VRP may also increase the likelihood of undershoot or overshoot, as described in the example of FIG. 5. The disclosed embodiments can prevent malfunction of the voltage converter 100, while reducing the ripple voltage and decreasing the likelihood of undershoot or overshoot.

The controller 130 may receive the ripple voltage VRP from the ripple addition circuit 120. The controller 130 may, in turn, switch the settings or mode of the converting circuit 110 based on the ripple voltage VRP. As an example, the controller 130 may adjust the converting circuit 110 based on the level information of the output voltage VO included in the ripple voltage VRP and information on time periods of a switching period included in the ripple voltage VRP.

FIG. 2 illustrates an operating method of the voltage converter 100, according to an embodiment of the present disclosure. Referring to FIGS. 1 and 2, in operation S110, the voltage converter 100 may convert the input voltage VIN to the output voltage VO. For example, the converting circuit 110 of the voltage converter 100 may convert the input voltage VIN to the output voltage VO in response to the switching control signals received from the controller 130.

In operation S120, the voltage converter 100 may generate the ripple voltage VRP by adding the ripple to the output voltage VO. For example, the ripple addition circuit 120 of the voltage converter 100 may generate the ripple from the first voltage V1 and may generate the ripple voltage VRP by adding the ripple to the output voltage VO.

In operation S130, the voltage converter 100 may adjust control timing based on the ripple voltage VRP. For example, the voltage converter 100 may adjust the switching timing of the converting circuit 110 based on the ripple voltage VRP.

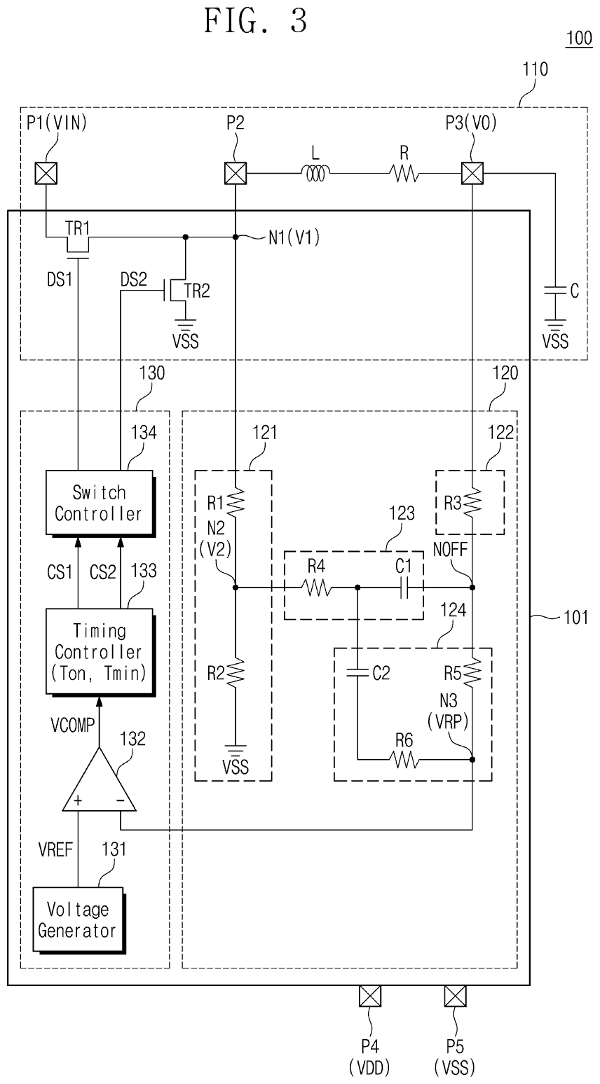

FIG. 3 illustrates a more detailed example of the voltage converter 100. Referring to FIGS. 1 and 3, the voltage converter 100 may include the converting circuit 110, the ripple addition circuit 120, and the controller 130.

The converting circuit 110 may include a first transistor TR1, a second transistor TR2, an inductor ‘L’, a resistor ‘R’, and a capacitor ‘C’. By way of example, the converting circuit 110 is illustrated as including the first transistor TR1 and the second transistor TR2, but the first transistor TR1 and the second transistor TR2 may be implemented with other active elements such as diodes capable of switching depending on a voltage.

The first transistor TRI may be one of switching elements of the converting circuit 110. The first transistor TR1 may include a first terminal connected to a first pad P1 to which the input voltage VIN is applied, a second terminal connected to a first node N1, and a gate controlled by a first driving signal DS1 of the controller 130.

The second transistor TR2 may be one of the switching elements of the converting circuit 110. The second transistor TR2 may include a first terminal connected to the first node N1, a second terminal connected to a ground node to which a ground voltage VSS is applied, and a gate controlled by a second driving signal DS2 of the controller 130.

The first node N1 may be connected to a second pad P2. The first voltage V1 of the first node N1 may be transferred to the ripple addition circuit 120.

The inductor ‘L’ and the resistor ‘R’ may be connected between the second pad P2 and a third pad P3. The capacitor ‘C’ may be connected between the third pad P3 and the ground node to which the ground voltage VSS is applied. The output voltage of the third pad P3 may be provided to an external load. In addition, the output voltage of the third pad P3 may be transferred to the ripple addition circuit 120.

Illustratively, the first transistor TR1 and the second transistor TR2 may be internal elements of a semiconductor die 101. The inductor ‘L’, the resistor ‘R’, and the capacitor ‘C’ are external elements of the semiconductor die 101 and may be provided to a substrate on which the semiconductor die 101 is mounted or a substrate on which the semiconductor package including the semiconductor die 101 is mounted.

The ripple addition circuit 120 may include a divider 121, an offset resistor 122, a first filter 123, and a second filter 124. The divider 121 may divide the first voltage V1 to generate a divided voltage, for example, a second voltage V2. The divider 121 may include a first resistor R1 connected between the first node N1 and a second node N2, and a second resistor R2 connected between the second node N2 and the ground node to which the ground voltage VSS is applied. The second voltage V2 of the second node N2 may be transferred to the first filter 123.

The offset resistor 122 may be connected between the third pad P3 and an offset node NOFF. The offset resistor 122 may suppress noise of the output voltage VO and to transfer it to the offset node NOFF. The offset resistor 122 may include a third resistor R3.

The first filter 123 may be a low-pass filter that performs low-pass filtering on the second voltage V2. The first filter 123 may include a fourth resistor R4 and a first capacitor C1 connected between the second node N2 and the offset node NOFF.

The second filter 124 may be a high-pass filter that performs high-pass filtering on the second voltage V2 (or the voltage of the offset node NOFF). For example, the second filter 124 may remove a direct current component from a voltage filtered by the first filter 123. The second filter 124 may include a fifth resistor R5 connected between the offset node NOFF and the third node N3, and a second capacitor C2 and a sixth resistor R6 connected between a node between the fourth resistor R4 and the first capacitor C1 and the third node N3.

The first filter 123 and the second filter 124 may generate a ripple from the second voltage V2. The ripple may be a signal with a level that periodically rises and falls. The ripple addition circuit 120 may add the ripple to the output voltage VO and may output the ripple voltage VRP through the third node N3.

The controller 130 may include a voltage generator 131, a comparator 132, a timing controller 133, and a switch controller 134. The voltage generator 131 may generate a reference voltage VREF. For example, the reference voltage VREF may be determined based on a level of the input voltage VIN and a target level of the output voltage VO. By way of example, the voltage generator 131 may be implemented as a voltage generator or a level shifter that generates the reference voltage VREF using a voltage received from an external device or a voltage used internally. As another example, the voltage generator 131 may be implemented as a voltage buffer (e.g., a voltage follower) that buffers a voltage received from an external device or a voltage used internally.

The comparator 132 may receive the reference voltage VREF through a positive input and the ripple voltage VRP through a negative input. The comparator 132 may compare the reference voltage VREF with the ripple voltage VRP, and may output the comparison result as a comparison voltage VCOMP. When the ripple voltage VRP is greater than the reference voltage VREF, the comparator 132 may output the comparison voltage VCOMP having a low level. When the ripple voltage VRP is less than the reference voltage VREF, the comparator 132 may output the comparison voltage VCOMP having a high level.

The timing controller 133 may receive the comparison voltage VCOMP from the comparator 132. The timing controller 133 may store information on an on time Ton and a minimum time Tmin. The on time Ton may be determined based on the input voltage VIN and the output voltage VO, and may be, for example, a value obtained by dividing the target level of the output voltage VO by the level of the input voltage VIN. As another example, the on time Ton may have a fixed value regardless of the input voltage VIN and output voltage VON. The minimum time Tmin may be determined based on the operating characteristics of the voltage converter 100 and the characteristics of the load to which the output voltage VO is transferred.

The timing controller 133 may control a first control signal CS1 and a second control signal CS2 based on the comparison voltage VCOMP, the on time Ton, and the minimum time Tmin. For example, the first control signal CS1 may be converted into the first driving signal DS1 by the switch controller 134 and may be transferred to a gate of the first transistor TR1. In detail, the first control signal CS1 may turn on and turn off the first transistor TRI by adjusting the voltage level of the gate of the first transistor TR1.

The second control signal CS2 may be converted into the second driving signal DS2 by the switch controller 134 and may be transferred to a gate of the second transistor TR2. In detail, the second control signal CS2 may turn on and turn off the second transistor TR2 by adjusting the voltage level of the gate of the second transistor TR2.

The switch controller 134 may convert the first control signal CS1 and the second control signal CS2 into the first driving signal DS1 and the second driving signal DS2, respectively, which have levels suitable for controlling the first transistor TR1 and the second transistor TR2. For example, the switch controller 134 may include a power stage or a level shifter.

In response to the comparison voltage VCOMP being at a low level or reaching a low level, the timing controller 133 may control the first control signal CS1 to a first level (e.g., a high level or a low level) to turn on the first transistor TR1, and may control the second control signal CS2 to a second level (e.g., a low level or a high level) to turn off the second transistor TR2. A period in which the first transistor TR1 is turned on and the second transistor TR2 is turned off may be referred to as an on period. For example, the time at which both the first transistor TR1 and the second transistor TR2 are turned on may be prohibited in a design stage of the voltage converter 100.

When the on time Ton elapses after the start of the on period, the timing controller 133 may control the first control signal CS1 to the second level to turn off the first transistor TR1, and may control the second control signal CS2 to the first level to turn on the second transistor TR2. A period in which the first transistor TR1 is turned off and the second transistor TR2 is turned on may be referred to as an off period. As an example, even if the comparison voltage VCOMP is at a low level, the timing controller 133 may maintain the off period for at least the minimum time Tmin. When the minimum time Tmin elapses, the timing controller 133 may operate in response to a level of the comparison voltage VCOMP. For example, the comparison voltage VCOMP is adjusted regardless of the minimum time Tmin, but the timing controller 133 may control the first control signal CS1 and the second control signal CS2 regardless of the comparison voltage VCOMP during the minimum time Tmin.

As an example, the voltage converter 100 may receive a power supply voltage VDD required for operation of the voltage converter 100 through a fourth pad P4. Additionally, the voltage converter 100 may receive the ground voltage VSS necessary for operation of the voltage converter 100 through a fifth pad P5.

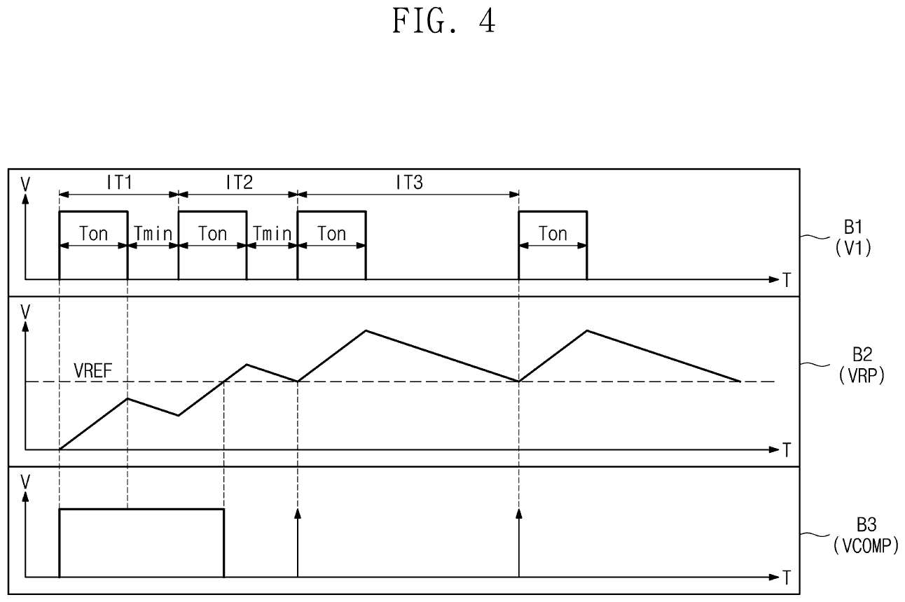

FIG. 4 illustrates examples of the first voltage V1, the ripple voltage VRP, and the comparison voltage VCOMP. Illustratively, examples of the first voltage V1, the ripple voltage VRP, and the comparison voltage VCOMP over time ‘T’ are illustrated in FIG. 4. A first box B1 illustrates a change in the first voltage V1. A second box B2 illustrates a change in the ripple voltage VRP. A third box B3 illustrates a change in the comparison voltage VCOMP. In FIG. 4, a horizontal axis represents the time ‘T’, and a vertical axis represents a voltage ‘V’.

Referring to FIGS. 3 and 4, during initialization, in a first period IT1, the ripple voltage VRP may be lower than the reference voltage VREF. For example, the ripple voltage VRP may be a ground voltage. Since the ripple voltage VRP is lower than the reference voltage VREF, the comparison voltage VCOMP may be at a high level. Since the comparison voltage VCOMP is at a high level, the first transistor TR1 may be turned on and the second transistor TR2 may be turned off. Accordingly, the on period begins, and the first voltage V1 may be at a high level having the level of the input voltage VIN. When the first voltage V1 becomes the input voltage VIN, the inductor ‘L’ and the capacitor ‘C’ may be charged by the input voltage VIN. As the inductor ‘L’ and capacitor ‘C’ are charged, the output voltage VO may gradually rise. In addition to charging the inductor ‘L’ and the capacitor ‘C’, the input voltage VIN may be transferred to the load connected to the third pad P3.

The ripple added to the ripple voltage VRP may be a signal in which the first voltage V1 is low-pass filtered by the first filter 123. Therefore, in the on period, the ripple may gradually rise. The ripple voltage VRP, which is the sum of the ripple and the output voltage VO, may also gradually rise.

After proceeding with the on period for the on time Ton in the first period IT1, the timing controller 133 may proceed with an off period for at least the minimum time Tmin. During the off period, the first transistor TR1 may be turned off, and the second transistor TR2 may be turned on. The first voltage V1 may be a low level having a level of the ground voltage VSS. When the first voltage V1 reaches the ground voltage VSS, the charges charged in the inductor ‘L’ and the capacitor ‘C’ may be transferred to the load connected to the third pad P3. Accordingly, the output voltage VO may gradually fall.

The ripple added to the ripple voltage VRP may be the signal in which the first voltage V1 is low-pass filtered by the first filter 123. Therefore, in the off period, the ripple may gradually fall. The ripple voltage VRP, which is the sum of the ripple and the output voltage VO, may also gradually fall.

After the minimum time Tmin elapses, the ripple voltage VRP may be lower than the reference voltage VREF. Accordingly, the comparison voltage VCOMP is at a high level, and the timing controller 133 may proceed with the on period of a second period IT2. In the on period, the ripple voltage VRP may gradually rise. For example, the ripple voltage VRP may be higher than the reference voltage VREF. When the ripple voltage VRP exceeds the reference voltage, the comparison voltage VCOMP may be at a low level.

After proceeding with the on period for the on time Ton, the timing controller 133 may proceed with the off period for at least the minimum time Tmin. In the off period, the ripple voltage VRP may gradually decrease. For example, the ripple voltage VRP may be equal to or lower than the reference voltage VREF. Accordingly, the comparison voltage VCOMP may be at a high level.

After the minimum time Tmin elapses, the comparison voltage VCOMP is at a high level, so the timing controller 133 may proceed with the on period of the third period IT3. In the on period, the ripple voltage VRP may gradually rise. For example, the ripple voltage VRP may be higher than the reference voltage VREF. When the ripple voltage VRP exceeds the reference voltage, the comparison voltage VCOMP may be at a low level.

After proceeding with the on period for the on time Ton, the timing controller 133 may proceed with the off period for at least the minimum time Tmin. In the off period, the ripple voltage VRP may gradually decrease. When the comparison voltage VCOMP is at a low level even after the minimum time Tmin elapses, the timing controller 133 may maintain the off period. For example, the timing controller 133 may maintain the off period until the ripple voltage VRP is equal to or lower than the reference voltage VREF, which causes the comparison voltage VCOMP to become a high level.

As an example, an operating mode in which the voltage converter 100 converts the input voltage VIN to the output voltage VOUT based on the on time Ton and the minimum time Tmin may be an initial operating mode of the voltage converter. An operating mode in which the voltage converter 100 converts the input voltage VIN to the output voltage VOUT based on the on time Ton and the off period that is longer than the minimum time Tmin may be a first operating mode of the voltage converter.

FIG. 5 illustrates examples of a first operating mode M1 and a second operating mode M2 of the voltage converter 100. Illustratively, an example of the ripple voltage VRP over the time ‘T’ is illustrated in FIG. 5. A fourth box B4 illustrates a change in the ripple voltage VRP in the first operating mode M1. A fifth box B5 illustrates a change in the ripple voltage VRP in the second operating mode M2. In FIG. 5, a horizontal axis represents the time “T”, and a vertical axis represents the voltage “V”.

Referring to FIGS. 3 and 5, in the first operating mode M1, the ripple voltage VRP may have levels as shown in a first time period I1 and a second time period I2. The first time period I1 may be from a first time T1 to a second time T2. The first time period I1 may correspond to an on period in which the ripple voltage VRP increases. The second time period I2 may be from the second time T2 to a third time T3. The second time period I2 may correspond to an off period in which the ripple voltage VRP decreases.

In the second operating mode M2, the ripple voltage VRP may have levels as shown in the first time period I1, the second time period 12, and a third time period I3. The first time period I1 may be from a fourth time T4 to a fifth time T5. The first time period I1 may correspond to an on period in which the ripple voltage VRP increases. The second time period I2 may be from the fifth time T5 to a sixth time T6. The second time period I2 may correspond to an off period in which the ripple voltage VRP decreases. The third time period 13 may be from the sixth time T6 to a seventh time T7. The third time period I3 may correspond to a dead period in which the ripple voltage VRP decreases more slowly than the second time period I2.

For example, when a load current consumed through the third pad P3 is relatively large, charges charged in the inductor ‘L’ and the capacitor ‘C’ may be consumed relatively quickly. The timing controller 133 may charge the inductor ‘L’ and the capacitor ‘C’ by starting the on period immediately after the off period.

For example, when the load current consumed through the third pad P3 is relatively small, charges charged in the inductor ‘L’ and capacitor ‘C’ may be consumed relatively slowly. For example, when the load current becomes ‘0’, charges charged in the inductor ‘L’ and the capacitor ‘C’ may flow to an external device through the first pad P1. The timing controller 133 may turn off the first transistor TR1 and the second transistor TR2 when the load current becomes ‘0’ to block the charges charged in the inductor ‘L’ and the capacitor ‘C’ from flowing to an external device through the first pad P1. As a result, the charges charged in the inductor ‘L’ and the capacitor ‘C’ may be consumed more slowly by the load than in the off period.

By way of example, the first operating mode M1 may be a continuous current mode (CCM). The second operating mode M2 may be a discontinuous current mode (DCM).

For example, when the amount of the load current supplied through the third pad P3 is relatively small, the voltage converter 100 may operate in the second operating mode M2. When the amount of the load current supplied through the third pad P3 is relatively large, the voltage converter 100 may operate in the first operating mode M1.

In detail, when the amount of the load current changes, the voltage converter 100 may transition between the first operating mode M1 and the second operating mode M2. When transitioning between the first operating mode M1 and the second operating mode M2, undershoot or overshoot may occur.

In addition, a difference between a DC level of the ripple voltage VRP of the first operating mode M1 and a DC level of the ripple voltage VRP of the second operating mode M2 may decrease a response speed at which the voltage converter 100 transitions the operating mode.

For example, by adjusting the size of the ripple added to the output voltage VO, operating characteristics such as undershoot and overshoot, and the difference between the DC level of the first operating mode M1 and the DC level of the second operating mode M2 may be adjusted. The smaller the size (e.g., amplitude) of the ripple, the less undershoot and overshoot, and the smaller the difference in DC levels may be. The smaller the size of the ripple, the better the operating characteristics of the voltage converter 100, and the better the response speed may be.

For example, the size of the ripple may be adjusted by adjusting the resistance value of the fourth resistor R4 of the first filter 123 or the capacitance of the first capacitor C1 of the first filter 123. By increasing the resistance value of the fourth resistor R4 of the first filter 123 or the capacitance of the first capacitor C1 of the first filter 123, the ripple may be reduced. When the resistance value of the fourth resistor R4 of the first filter 123 or the capacitance of the first capacitor C1 of the first filter 123 is reduced, the ripple may increase.

FIG. 6 illustrates an example of how the voltage converter 100 may malfunction when a ripple is reduced. Illustratively, examples of the ripple voltage VRP, the comparison voltage VCOMP, and the first voltage V1 over the time ‘T’ are illustrated in FIG. 6. A sixth box B6 illustrates a change in the ripple voltage VRP. A seventh box B7 illustrates a change in the comparison voltage VCOMP. An eighth box B8 illustrates a change in the first voltage V1. In FIG. 6, a horizontal axis represents a time “T”, and a vertical axis represents a voltage “V”.

Referring to FIGS. 3 and 6, the comparator 132 may have hysteresis. For example, the comparator 132 may perform comparison using an upper hysteresis voltage VHU and a lower hysteresis voltage VHL that are close to the reference voltage VREF. The comparator 132 may perform comparison by alternately using the upper hysteresis voltage VHU and the lower hysteresis voltage VHL.

The comparator 132 may compare the upper hysteresis voltage VHU with the ripple voltage VRP, then may compare the lower hysteresis voltage VHL with the ripple voltage VRP. Alternatively or additionally, comparator 132 may compare the lower hysteresis voltage VHL with the ripple voltage VRP, then may compare the upper hysteresis voltage VHU with the ripple voltage VRP. For example, the comparator 132 may alternately compare the upper hysteresis voltage VHU and the lower hysteresis voltage VHL with the ripple voltage VRP.

For example, to improve the safety of the voltage converter 100, the comparator 132 may be intentionally designed to have hysteresis. As another example, even if it was not intended when designing the voltage converter 100, the comparator 132 may have hysteresis due to environmental influences such as process, voltage, and temperature (PVT).

Illustratively, it is assumed that at the eighth time T8, the comparator 132 compares the lower hysteresis voltage VHL with the ripple voltage VRP. The ripple voltage VRP may reach (e.g., touch) TCH the lower hysteresis voltage VHL. For example, the ripple voltage VRP may be reduced to equal or less than the lower hysteresis voltage VHL. Afterwards, the comparator 132 may compare the upper hysteresis voltage VHU with the ripple voltage VRP.

The period from the eighth time T8 to the ninth time T9 may be an on period. However, since the ripple voltage VRP is lower than the upper hysteresis voltage VHU, the comparator 132 may output the comparison voltage VCOMP having a high level.

At the ninth time T9, when the on period ends, the controller 130 may proceed with the off period. Since the ripple voltage VRP is lower than the upper hysteresis voltage VHU, e.g., the comparison voltage VCOMP is at a high level, the controller 130 may control the converting circuit 110 to have the off period corresponding to the minimum time Tmin. The off period corresponding to the minimum time Tmin may be from the ninth time T9 to the tenth time T10. In the off period, the ripple voltage VRP may decrease.

At the tenth time T10, when the minimum time Tmin elapses, the ripple voltage VRP is lower than the upper hysteresis voltage VHU, e.g., the comparison voltage VCOMP is at a high level, so the controller 130 may end the off period and then may proceed with the next on period. Accordingly, the on period may be from the tenth time T10 to an eleventh time T11.

At the eleventh time T11, the ripple voltage VRP may reach (e.g., touch) the upper hysteresis voltage VHU. For example, the ripple voltage VRP may increase to equal or exceed the upper hysteresis voltage VHU. Afterwards, the comparator 132 may compare the lower hysteresis voltage VHL with the ripple voltage VRP.

When the on period ends at the eleventh time T11, the ripple voltage VRP is higher than the lower hysteresis voltage VHL, so the comparator 132 may output the comparison voltage VCOMP having a low level. The controller 130 may maintain the off period until the ripple voltage VRP is equal to or less than the lower hysteresis voltage VHL, e.g., until the comparison voltage VCOMP reaches a high level.

For example, if the comparator 132 has hysteresis, the voltage converter 100 may have two consecutive on periods with an off period of the minimum time Tmin in between. After two consecutive on periods, a relatively long off period may occur. In this example, the on period, the off period of the minimum time Tmin, the on period, and the relatively long off period may occur repeatedly in the form of a pattern.

Repeated transitions, in such a pattern form, may occur due to hysteresis of the comparator 132. Such a pattern of transitions may increase the ripple of the output voltage VO, and may cause the average level of the output voltage VO to differ from the target level. When the average level of the output voltage VO is different from the target level, the safety of the voltage converter 100, or an electronic device that receives the output voltage VO from the voltage converter 100, may deteriorate. The disclosed embodiments can address this safety issue.

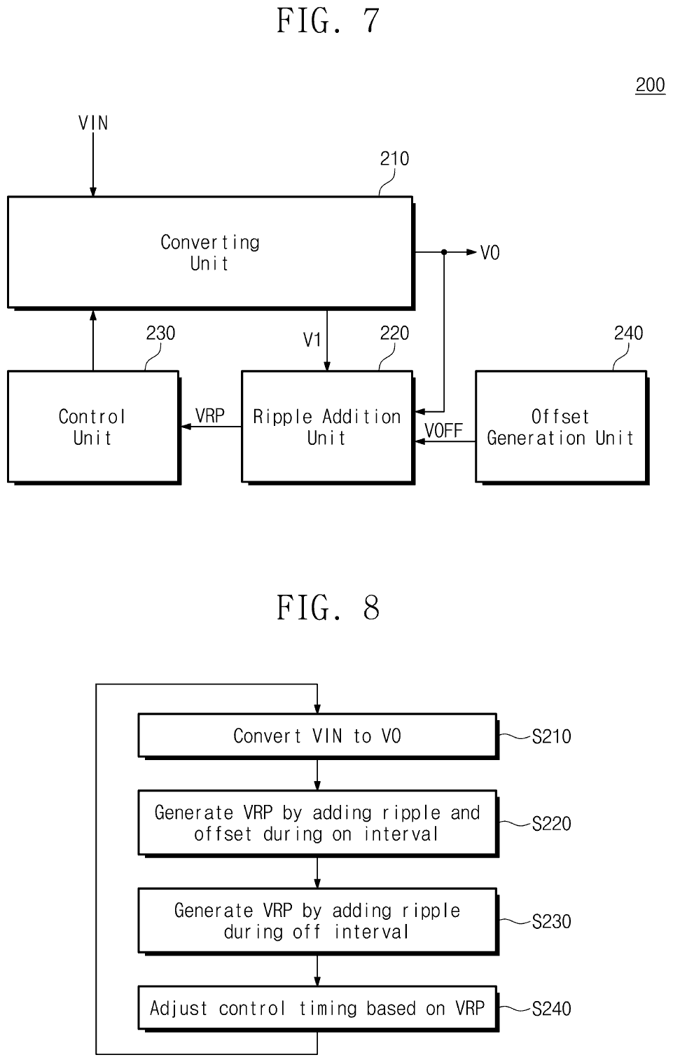

FIG. 7 illustrates a voltage converter 200, according to a second embodiment of the present disclosure. Referring to FIG. 7, the voltage converter 200 may include a converting unit or converting circuit 210 (e.g., a voltage converting circuit), a ripple addition unit or ripple addition circuit 220, a control unit or controller 230, and an offset generation unit or offset generation circuit 240. Compared with the voltage converter 100 of FIG. 1, the voltage converter 200 may additionally include the offset generation circuit 240.

The converting circuit 210 may receive an input voltage VIN. Based on a control from the controller 230 (e.g., a control signal sent from the controller 230), the converting circuit 210 may convert the input voltage VIN into an output voltage VO. For example, the converting circuit 210 may include a plurality of switching elements. In response to the controller 230 switching one or more of the plurality of switching elements, the converting circuit 210 may convert the input voltage VIN to the output voltage VO.

Illustratively, a level of the input voltage VIN may be fixed. A target level of the output voltage VO may be lower than the level of the input voltage VIN. In this example, the converting circuit 210 may perform a buck conversion, reducing the input to the target output level VO.

The ripple addition circuit 220 may then receive the output voltage VO and a first voltage V1 from the converting circuit 210. The first voltage V1 may be an internal voltage of the converting circuit 210. The ripple addition circuit 220 may generate a ripple voltage VRP based on the output voltage VO and the first voltage V1.

As an example, the ripple addition circuit 220 may generate a ripple corresponding to a switching period in which the controller 230 switches the converting circuit 210, based on the first voltage V1. For example, the ripple may rise during a first time period of the switching period and may fall during a second time period of the switching period. The ripple addition circuit 220 may add the ripple to the output voltage VO and may output the added result as a ripple voltage VRP. In this example, the ripple voltage VRP may rise during a first time period of the switching period and may fall during a second time period of the switching period.

The controller 230 may receive the ripple voltage VRP from the ripple addition circuit 220. The controller 230 may, in turn, switch the converting circuit 210 based on the ripple voltage VRP. As an example, the controller 230 may control the converting circuit 210 based on the level information of the output voltage VO included in the ripple voltage VRP and information on time periods of a switching period included in the ripple voltage VRP.

In this example, unlike in voltage converter 100 of FIG. 1, the offset generation circuit 240 may operate under the control of the controller 230. The offset generation circuit 240 may or may not generate an offset voltage VOFF under the control of the controller 230. When generating the offset voltage VOFF, the offset generation circuit 240 may provide the offset voltage VOFF to the ripple addition circuit 220. For example, under the control of controller 230, the offset generation circuit 240 may repeat periods of generating and not generating the offset voltage VOFF.

FIG. 8 illustrates an operating method of the voltage converter 200, according to an embodiment of the present disclosure. Referring to FIGS. 7 and 8, in operation S210, the voltage converter 200 may convert the input voltage VIN to the output voltage VO. For example, the converting circuit 210 of the voltage converter 200 may convert the input voltage VIN to the output voltage VO in response to the switching control signals received from the controller 230.

In operation S220, the voltage converter 200 may generate the ripple voltage VRP by adding the ripple and an offset during the on period. For example, the ripple addition circuit 220 of the voltage converter 200 may generate the ripple from the first voltage V1 and may add the ripple to the output voltage VO. Unlike in the method of FIG. 2, in this example the ripple addition circuit 220 may receive the offset voltage VOFF from the offset generation circuit 240 and may add the offset voltage VOFF to the output voltage. The ripple addition circuit 220 may generate the ripple voltage VRP by adding the ripple and the offset voltage VOFF to the output voltage VO.

In operation S230, the voltage converter 100 may generate the ripple voltage VRP by adding the ripple during the off period. For example, the ripple addition circuit 120 of the voltage converter 100 may generate the ripple from the first voltage V1 and may generate the ripple voltage VRP by adding the ripple to the output voltage VO.

In operation S240, the voltage converter 200 may adjust control timing based on the ripple voltage VRP. For example, the voltage converter 200 may adjust the switching timing of the converting circuit 210 based on the ripple voltage VRP.

For example, the ripple addition circuit 220 may generate different ripple voltages VRP in the on period and the off period.

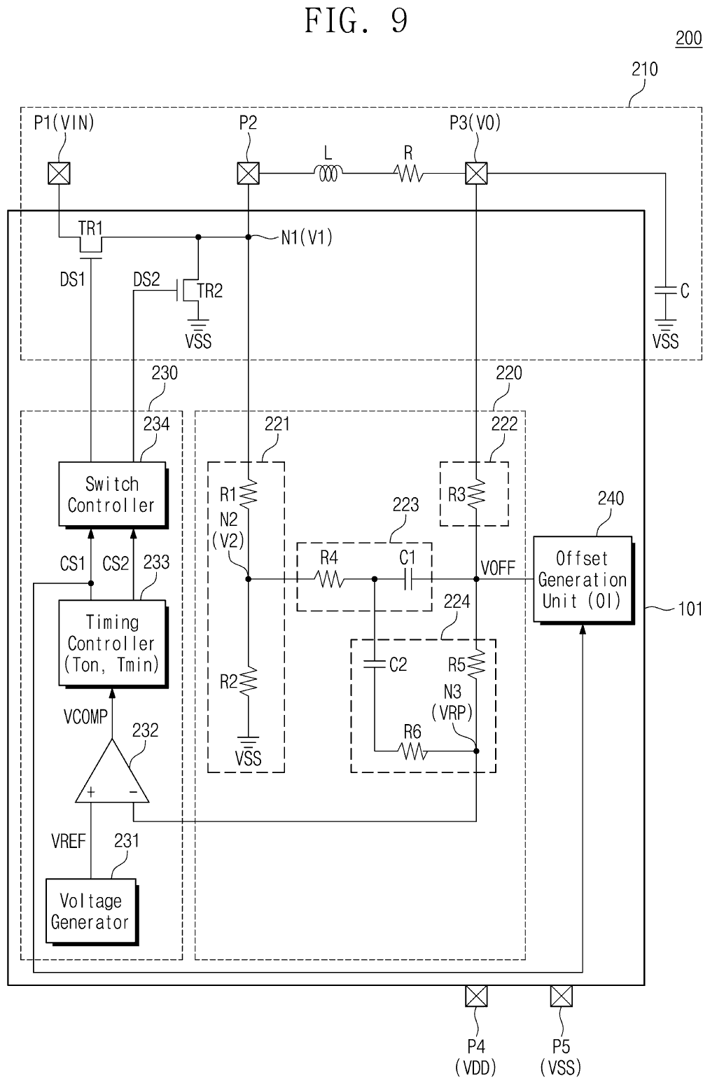

FIG. 9 illustrates a more detailed example of voltage converter 200. Referring to FIGS. 7 and 9, the voltage converter 200 may include the converting circuit 210, the ripple addition circuit 220, the controller 230, and the offset generation circuit 240. Compared with the voltage converter 100 of FIG. 3, the voltage converter 200 may additionally include the offset generation circuit 240.

The converting circuit 210 may include a first transistor TR1, a second transistor TR2, an inductor ‘L’, a resistor ‘R’, and a capacitor ‘C’.

The first transistor TRI may be one of the switching elements of the converting circuit 210. The first transistor TR1 may include a first terminal connected to a first pad P1 to which the input voltage VIN is applied, a second terminal connected to a first node N1, and a gate controlled by a first driving signal DS1 of the controller 230.

The second transistor TR2 may be one of the switching elements of the converting circuit 210. The second transistor TR2 may include a first terminal connected to the first node N1, a second terminal connected to a ground node to which the ground voltage VSS is applied, and a gate controlled by a second driving signal DS2 of the controller 230.

The first node N1 may be connected to a second pad P2. The first voltage V1 of the first node N1 may be transferred to the ripple addition circuit 220.

The inductor ‘L’ and the resistor ‘R’ may be connected between the second pad P2 and a third pad P3. The capacitor ‘C’ may be connected between the third pad P3 and the ground node to which the ground voltage VSS is applied. The output voltage of the third pad P3 may be provided to an external load. In addition, the output voltage of the third pad P3 may be transferred to the ripple addition circuit 220.

Illustratively, the first transistor TR1 and the second transistor TR2 may be internal elements of a semiconductor die 201. The inductor ‘L’, the resistor ‘R’, and the capacitor ‘C’ are external elements of the semiconductor die 201 and may be provided to a substrate on which the semiconductor die 201 is mounted or a substrate on which the semiconductor package including the semiconductor die 201 is mounted.

The ripple addition circuit 220 may include a divider 221, an offset resistor 222, a first filter 223, and a second filter 224. The divider 221 may divide the first voltage V1 to generate a divided voltage, for example, a second voltage V2. The divider 221 may include a first resistor R1 connected between the first node N1 and a second node N2, and a second resistor R2 connected between the second node N2 and the ground node to which the ground voltage VSS is applied. The second voltage V2 of the second node N2 may be transferred to the first filter 223.

The offset resistor 222 may be connected between the third pad P3 and an offset node NOFF. The offset resistor 222 may suppress noise of the output voltage VO and to transfer it to the offset node NOFF. The offset resistor 222 may include a third resistor R3.

The first filter 223 may be a low-pass filter that performs low-pass filtering on the second voltage V2. The first filter 223 may include a fourth resistor R4 and a first capacitor C1 connected between the second node N2 and the offset node NOFF.

The second filter 224 may be a high-pass filter that performs high-pass filtering on the second voltage V2 (or the voltage of the offset node NOFF). For example, the second filter 224 may remove a direct current component from a voltage filtered by the first filter 223. The second filter 224 may include a fifth resistor R5 connected between the offset node NOFF and the third node N3, and a second capacitor C2 and a sixth resistor R6 connected between a node between the fourth resistor R4 and the first capacitor C1 and the third node N3.

The first filter 223 and the second filter 224 may generate a ripple from the second voltage V2. The ripple may be a signal with a level that periodically rises and falls. The ripple addition circuit 220 may add the ripple to the output voltage VO and may output the ripple voltage VRP through the third node N3.

The controller 230 may include a voltage generator 231, a comparator 232, a timing controller 233, and a switch controller 234. The voltage generator 231 may generate a reference voltage VREF. For example, the reference voltage VREF may be determined based on a level of the input voltage VIN and a target level of the output voltage VO. By way of example, the voltage generator 231 may be implemented as a voltage generator or a level shifter that generates the reference voltage VREF using a voltage received from an external device or a voltage used internally. As another example, the voltage generator 231 may be implemented as a voltage buffer (e.g., a voltage follower) that buffers a voltage received from an external device or a voltage used internally.

The comparator 232 may receive the reference voltage VREF through a positive input and the ripple voltage VRP through a negative input. The comparator 232 may compare the reference voltage VREF with the ripple voltage VRP, and may output the comparison result as a comparison voltage VCOMP. When the ripple voltage VRP is greater than the reference voltage VREF, the comparator 232 may output the comparison voltage VCOMP having a low level. When the ripple voltage VRP is less than the reference voltage VREF, the comparator 232 may output the comparison voltage VCOMP having a high level.

The timing controller 233 may receive the comparison voltage VCOMP from the comparator 232. The timing controller 233 may store information regarding an on time Ton and a minimum time Tmin. The on time Ton may be determined based on the input voltage VIN and the output voltage VO, and may be, for example, a value obtained by dividing the target level of the output voltage VO by the level of the input voltage VIN. The minimum time Tmin may be determined based on the operating characteristics of the voltage converter 200 and the characteristics of the load to which the output voltage VO is transferred.

The timing controller 233 may control a first control signal CS1 and a second control signal CS2 based on the comparison voltage VCOMP, the on time Ton, and the minimum time Tmin. For example, the first control signal CS1 may be converted into the first driving signal DS1 by the switch controller 234 and may be transferred to a gate of the first transistor TR1. In particular, the first control signal CS1 may turn on and turn off the first transistor TR1 by adjusting the voltage level of the gate of the first transistor TR1.

The second control signal CS2 may be converted into the second driving signal DS2 by the switch controller 234 and may transferred to a gate of the second transistor TR2. For example, the second control signal CS2 may turn on and turn off the second transistor TR2 by adjusting the voltage level of the gate of the second transistor TR2.

The switch controller 234 may convert the first control signal CS1 and the second control signal CS2 into the first driving signal DS1 and the second driving signal DS2, respectively, which have levels suitable for controlling the first transistor TR1 and the second transistor TR2. For example, the switch controller 234 may include a power stage or a level shifter.

In response to the comparison voltage VCOMP being at a low level or reaching a low level, the timing controller 233 may control the first control signal CS1 to a first level (e.g., a high level or a low level) to turn on the first transistor TR1, and may control the second control signal CS2 to a second level (e.g., a low level or a high level) to turn off the second transistor TR2. A period in which the first transistor TR1 is turned on and the second transistor TR2 is turned off may be referred to as an on period.

When the on time Ton elapses after the start of the on period, the timing controller 233 may control the first control signal CS1 to the second level to turn off the first transistor TR1, and may control the second control signal CS2 to the first level to turn on the second transistor TR2. A period in which the first transistor TR1 is turned off and the second transistor TR2 is turned on may be referred to as an off period. As an example, even if the comparison voltage VCOMP is at a low level, the timing controller 233 may maintain the off period for at least the minimum time Tmin. When the minimum time Tmin elapses, the timing controller 233 may operate in response to a level of the comparison voltage VCOMP.

The offset generation circuit 240 may receive the first control signal CS1 from the timing controller 233. In response to the first control signal CS1 being activated, the offset generation circuit 240 may generate the offset voltage VOFF. In response to the first control signal CS1 being deactivated, the offset generation circuit 240 may not generate the offset voltage VOFF. For example, the offset generation circuit 240 may generate the offset voltage VOFF during the on period, and may not generate the offset voltage VOFF when it is not the on period.

The generated offset voltage VOFF may be transferred to the offset node NOFF. For example, the ripple addition circuit 220 may generate the ripple voltage VRP by adding the ripple and the offset voltage VOFF to the output voltage VO. As an example, the offset generation circuit 240 may generate the offset voltage VOFF based on offset information OI.

As an example, the voltage converter 200 may receive the power supply voltage VDD required for operation of the voltage converter 200 through a fourth pad P4. Additionally, the voltage converter 200 may receive the ground voltage VSS necessary for operation of the voltage converter 200 through a fifth pad P5.

FIG. 10 illustrates an example of how the voltage converter 200 operates when the comparator 232 has hysteresis. Referring to FIGS. 9 and 10, examples of the ripple voltage VRP, the comparison voltage VCOMP, and the first voltage V1 over time ‘T’ are illustrated in FIG. 10. A ninth box B9 illustrates a change over time in the ripple voltage VRP. A tenth box B10 illustrates a change in the comparison voltage VCOMP. An eleventh box B11 illustrates a change in the first voltage V1. In FIG. 10, a horizontal axis represents the time “T”, and a vertical axis represents the voltage “V”.

Referring to FIGS. 9 and 10, the comparator 232 may have hysteresis. For example, the comparator 232 may perform comparison using an upper hysteresis voltage VHU and a lower hysteresis voltage VHL that are close to the reference voltage VREF. The comparator 232 may perform comparison by alternately using the upper hysteresis voltage VHU and the lower hysteresis voltage VHL.

The comparator 232 may compare the upper hysteresis voltage VHU with the ripple voltage VRP, then may compare the lower hysteresis voltage VHL with the ripple voltage VRP, and may compare the lower hysteresis voltage VHL with the ripple voltage VRP, then may compare the upper hysteresis voltage VHU with the ripple voltage VRP. For example, the comparator 232 may alternately compare the upper hysteresis voltage VHU and the lower hysteresis voltage VHL with the ripple voltage VRP.

For example, to improve the safety of the voltage converter 200, the comparator 232 may be intentionally designed to have hysteresis. As another example, even if it was not intended when designing the voltage converter 100, the comparator 132 may have hysteresis due to environmental influences such as process, voltage, and temperature (PVT).

Illustratively, it is assumed that at a thirteenth time T13, the comparator 232 compares the lower hysteresis voltage VHL with the ripple voltage VRP. The ripple voltage VRP may reach (e.g., touch) TCH the lower hysteresis voltage VHL. For example, the ripple voltage VRP may be reduced to equal or less than the lower hysteresis voltage VHL. Afterwards, the comparator 232 may compare the upper hysteresis voltage VHU with the ripple voltage VRP.

The period from the thirteenth time T13 to the fourteenth time T14 may be an on period. In the on period, the offset generation circuit 240 may generate the offset voltage VOFF. As an example, the offset voltage VOFF may be determined based on the hysteresis of the comparator 232. For example, the offset voltage VOFF may be determined based on the difference (e.g., hysteresis level) between the upper hysteresis voltage VHU and the lower hysteresis voltage VHL of the comparator 232. The offset voltage VOFF may be set to be equal to or greater than the hysteresis level. Information about the level of the offset voltage VOFF may be determined in the offset generation circuit 240 as offset information OI. The offset generation circuit 240 may generate the offset voltage VOFF based on the offset information OI.

When the offset generation circuit 240 generates the offset voltage VOFF, the ripple voltage VRP may rise further by the offset voltage VOFF. When the offset voltage VOFF is equal to or greater than the hysteresis level, and when the ripple voltage VRP reaches (e.g., touches) TCH the lower hysteresis voltage VHL, the ripple voltage VRP may rise to a level higher than the upper hysteresis voltage VHU. Accordingly, the comparator 232 may output the comparison voltage VCOMP having a low level. In detail, the comparison voltage VCOMP may temporarily appear in the form of a pulse having a high level at the thirteenth time T13.

When the ripple voltage VRP rises to a level higher than the upper hysteresis voltage VHU, the ripple voltage VRP may reach (e.g., touch) TCH the upper hysteresis voltage VHU. Accordingly, the comparator 232 may compare the lower hysteresis voltage VHL with the ripple voltage VRP.

At the fourteenth time T14, when the on period ends, the controller 230 may proceed with the off period. When the off period begins at the fourteenth time T14, the offset generation circuit 240 may stop generating the offset voltage VOFF. Accordingly, the ripple voltage VRP may be lowered by the offset voltage VOFF. Even if the ripple voltage VRP is lowered by the offset voltage VOFF, the ripple voltage VRP may be higher than the lower hysteresis voltage VHL.

Since the ripple voltage VRP is higher than the lower hysteresis voltage VHL, e.g., the comparison voltage VCOMP is at a low level, the controller 230 may control the converting circuit 210 to have the off period corresponding to at least the minimum time Tmin. The off period corresponding to at least the minimum time Tmin may be from the fourteenth time T14 to the fifteenth time T15. In the off period, the ripple voltage VRP may decrease.

After a time longer than the minimum time Tmin elapses, at the fifteenth time T15, the ripple voltage VRP may be equal to or lower than the lower hysteresis voltage VHL. For example, the ripple voltage VRP may reach (e.g., touch) the lower hysteresis voltage VHL. Afterwards, the comparator 232 may compare the upper hysteresis voltage VHU with the ripple voltage VRP.

When the ripple voltage VRP reaches (e.g., touches) the lower hysteresis voltage VHL, the controller 230 may end the off period and may proceed with the on period. The on period may start from the fifteenth time T15. At the fifteenth time T15, the offset generation circuit 240 may generate the offset voltage VOFF again. Accordingly, the ripple voltage VRP increases by the offset voltage VOFF and may reach (e.g., touch) TCH the upper hysteresis voltage VHU. Afterwards, the comparator 232 may compare the lower hysteresis voltage VHL with the ripple voltage VRP.

As described above, the voltage converter 200 according to an embodiment of the present disclosure can add the offset voltage VOFF to the ripple voltage VRP at the start of the on period, so that the ripple voltage VRP may reach (e.g., touch) TCH the upper hysteresis voltage VHU. Additionally, by stopping the generation of the offset voltage VOFF at the end of the on period, the ripple voltage VRP is compared with the lower hysteresis voltage VHL. Thus, the voltage converter 200 may compensate for the hysteresis level of the comparator 232 using the offset voltage VOFF, and may compare the lower hysteresis voltage VHL with the ripple voltage VRP.

By virtue of adding the offset voltage VOFF during the on period, the voltage converter 200 may operate normally even if the level of ripple added by the ripple addition circuit 220 is below the hysteresis level. Accordingly, the size (e.g., amplitude) of the ripple may be smaller than the hysteresis level, thereby improving the operating characteristics of the voltage converter 200 (e.g., reducing the overshoot or the undershoot), and improving a response speed (e.g., reducing the difference between the DC levels of the first and second operating modes).

Illustratively, the voltage converter 200 may enter the second operating mode (e.g., the DCM) when the load current becomes ‘0’ while the comparison voltage VCOMP is at a low level. As a result, the malfunction described with reference to FIG. 6 may not occur in the second operating mode using the disclosed voltage converter 200. Accordingly, the voltage converter 200 may control the offset generation circuit 240 to generate the offset voltage VOFF in the on period only in the first operating mode (e.g., the CCM). The voltage converter 200 may allow the offset generation circuit 240 not to generate the offset voltage VOFF in the second operating mode (e.g., DCM mode).

FIG. 11 illustrates the offset generation circuit 240, according to an embodiment of the present disclosure. Referring to FIGS. 9 and 11, the offset generation circuit 240 may include a first offset transistor OT1, a second offset transistor OT2, a third offset transistor OT3, an offset resistor OR, and a storage element SE.

The first offset transistor OT1 may include a first terminal connected to a power node supplied with the power supply voltage VDD or a voltage higher than the output voltage VO, a gate connected to a gate of the second offset transistor OT2, and a second terminal through which the offset voltage VOFF is output.

The second offset transistor OT2 may include a first terminal connected to the power node to which the power supply voltage VDD is supplied, the gate connected to the gate of the first offset transistor OT1, and a second terminal connected to the gate of the second offset transistor OT2.

The third offset transistor OT3 may include a first terminal connected to the offset resistor OR, a gate to which the first control signal CS1 is supplied, and a second terminal connected to a ground node to which the ground voltage VSS is supplied.

The offset resistor OR may be connected between the second terminal of the second offset transistor OT2 and the first terminal of the third offset transistor OT3. The offset resistor OR may be a variable resistor. The resistance value of the offset resistor OR may be determined based on a code CD. As another example, the offset resistor OR may be implemented as a fixed resistor.

The storage element SE may store the code CD. For example, the storage element SE may store the code CD as the offset information OI. The code CD may be stored in the storage element SE by an external device. For example, the code CD may be stored in the storage element SE through an interface such as a general purpose IO (GPIO) after the voltage converter 200 is manufactured. Alternatively, the code CD may be written in the storage element SE during manufacturing of the storage element SE, and the storage element SE may be mounted on the voltage converter 200. As another example, the storage element SE may include laser fuses or electrical fuses and may store the code CD using the laser fuses or the electrical fuses.

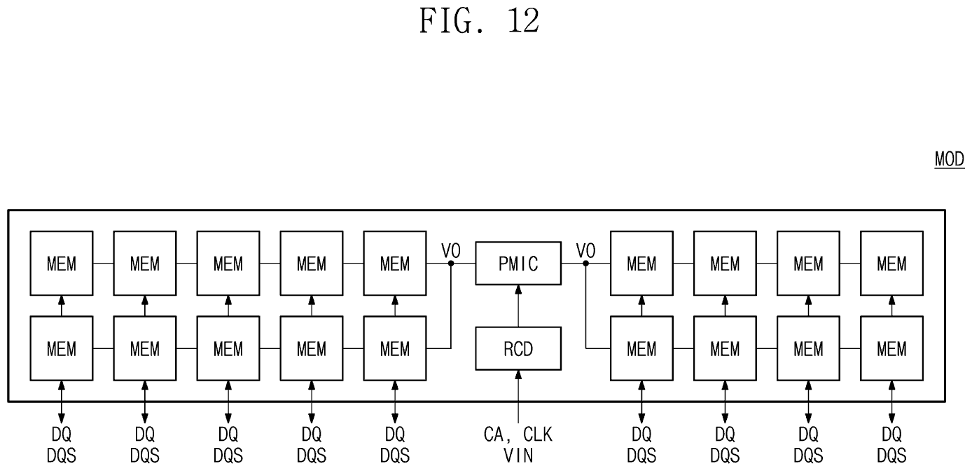

FIG. 12 illustrates a memory module MOD, according to an embodiment of the present disclosure. Referring to FIG. 12, the memory module MOD may include memory devices MEM, a register clock driver RCD, and a power management circuit PMIC.

Each of the memory devices MEM may communicate data signals DQ and data strobe signals DQS with an external device. Illustratively, the memory devices MEM are illustrated as being arranged in two rows and nine columns, but the number and arrangement of the memory devices MEM are not limited thereto.

The register clock driver RCD may receive a command and address CA and a clock signal CLK from an external device. The register clock driver RCD may commonly provide the command and address CA and the clock signal CLK to the memory devices MEM.

The power management device PMIC may receive the input voltage VIN from an external device. The power management device PMIC may include the voltage converter 200. The voltage converter 200 may generate the offset voltage VOFF in the on period and add it to the ripple voltage VRP, and may not generate the offset voltage VOFF in the off period.

The power management device PMIC may convert the input voltage VIN to the output voltage VO using the voltage converter 200. The power management device PMIC may commonly provide the output voltage VO to the memory devices MEM. The power management device PMIC may provide the output voltage VO to the register clock driver RCD, or may provide another output voltage converted from the input voltage VIN to the register clock driver RCD.

Illustratively, the memory module MOD may communicate with an external device based on a dual in-line memory module (DIMM), an RDIMM, or an LRDIMM.

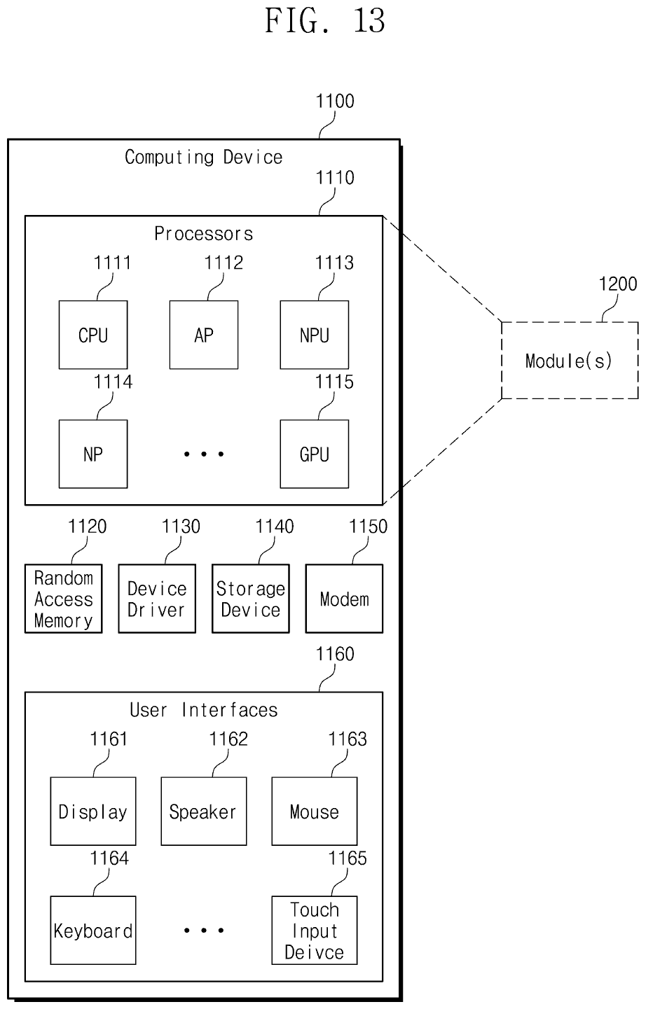

FIG. 13 is a block diagram illustrating a computing device 1100, according to an embodiment of the present disclosure. Referring to FIG. 13, the computing device 1100 may include processors 1110, a random access memory 1120, a device driver 1130, a storage device 1140, a MODEM 1150, and user interfaces 1160.

The processors 1110 may include, for example, at least one general-purpose processor such as a central processing unit (CPU) 1111 or an application processor (AP) 1112. The processors 1110 may also include at least one special purpose processor (or a hardware accelerator), such as a neural processing unit 1113, a neuromorphic processor 1114, a graphics processing unit (GPU) 1115, etc. The processors 1110 may include two or more homogeneous processors.

The random access memory 1120 may be used as a working memory of the processors 1110 and may be used as a main memory or a system memory of the computing device 1100. The random access memory 1120 may include a volatile memory such as a dynamic random access memory or a static random access memory or a nonvolatile memory such as a phase-change random access memory, a ferroelectric random access memory, a magnetic random access memory, or a resistive random access memory.

The device driver 1130 may control the following peripheral devices depending on a request of the processors 1110: the storage device 1140, the MODEM 1150, and the user interfaces 1160. The storage device 1140 may include a stationary storage device such as a hard disk drive or a solid state drive, or a removable storage device such as an external hard disk drive, an external solid state drive, or a removable memory card.

The MODEM 1150 may provide remote communication with an external device. The MODEM 1150 may perform wired or wireless communication with the external device. The MODEM 1150 may communicate with the external device based on at least one of various communication schemes such as Ethernet, wireless-fidelity (Wi-Fi), long term evolution (LTE), and 5th generation (5G) mobile communication.

The user interfaces 1160 may receive information from a user and may provide information to the user. The user interfaces 1160 may include at least one user output interface such as a display 1161 or a speaker 1162, and at least one user input interface such as a mice 1163, a keyboard 1164, or a touch input device 1165.

The instructions (or codes) of a module(s) 1200 may be received through the MODEM 1150 and may be stored in the storage device 1140. The instructions (or codes) of the module(s) 1200 may be stored in a removable storage device, and the removable storage device may be connected with the computing device 1100. The instructions (or codes) of the module(s) 1200 may be loaded onto the random access memory 1120 from the storage device 1140 and may be executed on the random access memory 1120.

By way of example, the random access memory 1120 may include the memory module MOD described with reference to FIG. 12. The memory module MOD may include the power management device PMIC. The power management device PMIC may receive the input voltage VIN from an external device. The power management device PMIC may include the voltage converter 200. The voltage converter 200 may generate the offset voltage VOFF in the on period and add it to the ripple voltage VRP, and may not generate the offset voltage VOFF in the off period. The power management device PMIC may convert the input voltage VIN to the output voltage VO using the voltage converter 200. The power management device PMIC may commonly provide the output voltage VO to the memory devices MEM.

Illustratively, the processors 1110 may execute the module(s) 1200. The module(s) 1200 may support the manufacturing of the memory module MOD, the power management device PMIC of the memory module MOD, or the voltage converter 200 of the power management device PMIC.

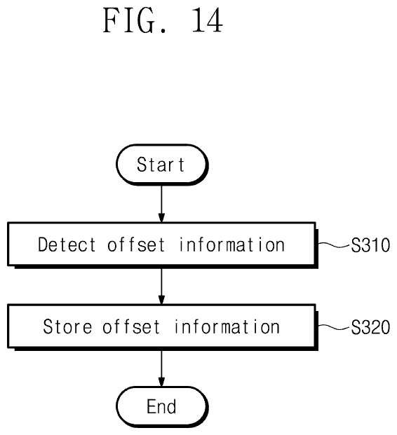

FIG. 14 illustrates an example of an operating method of the computing device 1100. Illustratively, an example of how the module(s) 1200 executed by the processors 1110 supports manufacturing of the memory module MOD, the power management device PMIC of the memory module MOD, or the voltage converter 200 of the power management device PMIC is illustrated in FIG. 14.

Referring to FIGS. 13 and 14, in operation S310, the computing device 1100 may detect the offset information OI. For example, the computing device 1100 may detect the offset information OI through simulation or machine learning-based inference based on the design layout of the voltage converter 200, the controller 230, or the comparator 232. For example, the computing device 1100 may detect the offset information OI to prevent the malfunction described with reference to FIG. 6.

Alternatively, the computing device 1100 may detect the offset information OI by performing measurement on the manufactured voltage converter 200, the manufactured controller 230, or the manufactured comparator 232. Illustratively, the computing device 1100 may perform measurements on a plurality of voltage converters, a plurality of controllers, or a plurality of comparators, and may detect an average value or a maximum value of the offset information as the offset information OI.

In operation S320, the computing device 1100 may store the offset information OI. For example, the computing device 1100 may store the code CD as the offset information OI in the storage element SE of the offset generation circuit 240 of the voltage converter 200.

Illustratively, the computing device 1100 may store the offset information OI in the storage element SE after the storage element SE is manufactured. The storage element SE storing the offset information OI may be mounted on the offset generation circuit 240 when manufacturing the voltage converter 200.

As another example, the computing device 1100 may store the offset information OI in the storage element SE after the voltage converter 200 is manufactured.

In the above embodiments, components according to the present disclosure are described by using the terms “first”, “second”, “third”, and the like. However, the terms “first”, “second”, “third”, and the like may be used to distinguish components from each other and do not limit the present disclosure. For example, the terms “first”, “second”, “third”, and the like do not involve an order or a numerical meaning of any form.

In the above embodiments, components according to embodiments of the present disclosure are described by using blocks and may be described as “units.” The blocks and/or units may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. In addition, the blocks may include circuits composed of semiconductor devices in the IC or circuits registered as Intellectual Property (IP).

According to an embodiment of the present disclosure, by adding an offset voltage, the size of the ripple that the voltage converter injects into the output voltage may be further reduced. Accordingly, a voltage converter having improved response speed and improved operation characteristics, a memory module including the voltage converter, and a method of operating the voltage converter are provided.

The above descriptions refers to detail embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. Therefore, the scope of the present disclosure should not be limited to the above-described embodiments and should be defined by not only the claims to be described later, but also those equivalent to the claims of the present disclosure.

What is claimed is:

1. A voltage converter comprising:
a voltage converting circuit configured to convert an input voltage into an output voltage;
an offset generation circuit configured to generate an offset voltage;
a ripple addition circuit configured to receive the output voltage and a first voltage from the voltage converting circuit, to receive the offset voltage from the offset generation circuit, and to generate a ripple voltage based on the output voltage, the first voltage, and the offset voltage; and
a controller configured to receive the ripple voltage, to control switches in the voltage converting circuit based on the ripple voltage, and to control a timing at which the offset generation circuit generates the offset voltage and a timing at which the offset generation circuit does not generate the offset voltage.

2. The voltage converter of claim 1, wherein the controller is configured to cause the offset generation circuit to generate the offset voltage during a time period when the output voltage rises, andto prevent the offset generation circuit from generating the offset voltage during a time period when the output voltage falls.

3. The voltage converter of claim 1, wherein the controller includes a comparator configured to compare the ripple voltage with a reference voltage and to generate a comparator voltage as a result of the comparison, and
wherein the offset voltage is determined based on a hysteresis of the comparator.

4. The voltage converter of claim 3, wherein a level of the offset voltage is determined to be equal to or greater than a level of the hysteresis of the comparator.

5. The voltage converter of claim 1, wherein the offset generation circuit includes:
a first transistor including a first terminal connected to a power node to which a power supply voltage is supplied, a second terminal configured to output the offset voltage, and a gate connected to a first node;
a second transistor including a third terminal connected to the power node, a fourth terminal connected to the first node, and a second gate connected to the first node;
a variable resistor connected between the first node and a second node; and
a third transistor including a fifth terminal connected to the second node, a sixth terminal connected to a ground node to which a ground voltage is supplied, and a third gate configured to receive a control signal from the controller.

6. The voltage converter of claim 5, wherein the offset voltage is determined based on a resistance value of the variable resistor.

7. The voltage converter of claim 5, wherein:
the offset generation circuit includes a storage element configured to store a code for determining a resistance value of the variable resistor; and
the code is stored in the storage element by an external device.

8. The voltage converter of claim 1, wherein the ripple addition circuit is configured to generate a ripple based on the first voltage, and to add the ripple and the offset voltage to the output voltage so as to be output as the ripple voltage.

9. The voltage converter of claim 1, wherein the ripple addition circuit includes:
a voltage divider configured to receive the first voltage, and to divide the first voltage so as to be output;
a noise suppression circuit configured to suppress noise of the output voltage so as to be transmitted to an offset node;
a first filter configured to perform low-pass filtering on the divided first voltage so as to be transferred to the offset node; and
a second filter configured to perform high-pass filtering on a voltage of the offset node so as to be output as the ripple voltage.

10. The voltage converter of claim 9, wherein the offset generation circuit is configured to provide the offset voltage to the offset node.

11. The voltage converter of claim 1, wherein the voltage converting circuit includes:
a first switch electrically connecting an output node where the output voltage is output to an input node where the input voltage is received; and
a second switch electrically connecting the output node to a ground node to which a ground voltage is supplied.

12. The voltage converter of claim 11, wherein the controller includes:
a comparator configured to compare the ripple voltage with a reference voltage and to output a comparison voltage as a result of the comparison; and
a timing controller configured to generate a first control signal to turn on and turn off the first switch, and to generate a second control signal to turn on and turn off the second switch, based on the comparison voltage.

13. The voltage converter of claim 12, wherein the controller allows the offset generation circuit to generate the offset voltage using the first control signal.

14. The voltage converter of claim 11, wherein the controller has a first operating mode for controlling the first switch and the second switch in a first manner and a second operating mode for controlling the first switch and the second switch in a second manner, and
wherein, in the first operating mode, the controller is configured to control the timing at which the offset generation circuit generates the offset voltage and the timing at which the offset generation circuit does not generate the offset voltage, and
wherein, in the second operating mode, the controller allows the offset generation circuit not to generate the offset voltage.

15. The voltage converter of claim 14, wherein, in the first operating mode, the controlleris configured to repeat turning on the first switch during a first time period and turning off the second switch, and turning off the first switch during a second time period and turning on the second switch.

16. The voltage converter of claim 14, wherein, in the second operating mode, the controlleris configured to repeat turning on the first switch during a first time period and turning off the second switch, turning off the first switch during a second time period and turning on the second switch, and turning off the first switch during a third time period and turning off the second switch.

17. A memory module comprising:
a plurality of memory devices;
a driver configured to receive commands, addresses, and clock signals from an external device, and to transfer the commands, the addresses, and the clock signals to the plurality of memory devices; and
a voltage converter configured to receive an input voltage from the external device, to convert the input voltage into an output voltage, and to provide the output voltage to the plurality of memory devices,
wherein the voltage converter includes:
a voltage converting circuit configured to convert the input voltage into the output voltage;
an offset generation circuit configured to generate an offset voltage;
a ripple addition circuit configured to receive the output voltage and a first voltage from the voltage converting circuit, to receive the offset voltage from the offset generation circuit, and to generate a ripple voltage based on the output voltage, the first voltage, and the offset voltage; and
a controller configured to receive the ripple voltage, to control the voltage converting circuit based on the ripple voltage, and to control a timing at which the offset generation circuit generates the offset voltage and a timing at which the offset generation circuit does not generate the offset voltage.

18. The memory module of claim 17, wherein the offset generation circuit includes:
a first transistor including a first terminal connected to a power node to which a power supply voltage is supplied, a second terminal configured to output the offset voltage, and a gate connected to a first node;
a second transistor including a third terminal connected to the power node, a fourth terminal connected to the first node, and a second gate connected to the first node;
a variable resistor connected between the first node and a second node; and
a third transistor including a fifth terminal connected to the second node, a sixth terminal connected to a ground node to which a ground voltage is supplied, and a third gate configured to receive a control signal from the controller.

19. The memory module of claim 18, wherein the ripple addition circuit includes:
a voltage divider configured to receive the first voltage, and to divide the first voltage so as to be output;
a noise suppression circuit configured to suppress noise of the output voltage so as to be transmitted to an offset node;
a first filter configured to perform a low-pass filtering on the divided first voltage so as to be transferred to the offset node; and
a second filter configured to perform a high-pass filtering on a voltage of the offset node so as to be output as a ripple, and
wherein the offset generation circuit is configured to provide the offset voltage to the offset node.

20. A method of operating a voltage converter, the method comprising:
based on a switching control signal, converting an input voltage to generate an output voltage from the input voltage;
in a first time period, generating a ripple voltage by adding a ripple and an offset to the output voltage;
in a second time period, generating the ripple voltage by adding the ripple to the output voltage; and
adjusting a timing of converting the input voltage based on the ripple voltage in the first time period and the second time period.
